(19) United States
(12) Patent Application Publication
(10) Pub. No.: US 2014/0369010 A1
(43) Pub. Date: Dec. 18, 2014

(54) IMAGE DISPLAY APPARATUS PROVIDED WITH BACK COVER

(71) Applicant: Yu Fushimi, Osaka (JP)

(72) Inventor: Yu Fushimi, Osaka (JP)

(73) Assignee: PANASONIC CORPORATION, Osaka (JP)

(21) Appl. No.: 14/373,335

(22) PCT Filed: Jan. 27, 2012
(86) PCT No.: PCT/JP2012/000540

§ 371 Date: Jul. 18, 2014

(51) Int. Cl. H05K 7/14; H05K 1/18

(52) U.S. Cl. CPC H05K 7/1458; H05K 1/181; H05K 2201/10128; H05K 2201/1003
USPC 361/752

(57) ABSTRACT

By use of the present invention, noise would not be generated from a metallic back cover of an image display apparatus in which a toroidal coil in the internal circuit and the metallic back cover are arranged close to each other. The image display apparatus includes a circuit board on which a toroidal coil is mounted, and a back cover covering a back face. The back cover has at least one hole configured to reduce the influence of a magnetic flux generated by the toroidal coil, the hole being provided in a region including a region facing the toroidal coil on the circuit board. The at least one hole may include a plurality of holes arranged in a grid pattern.

### TECHNICAL FIELD

The present disclosure relates to a back cover of an image display apparatus such as a plasma display television (TV).

### BACKGROUND ART

In the field of plasma display TVs or liquid crystal TVs, a reduction in the thickness of image display apparatuses is remarkably progressing by virtue of employing a thin power circuit, a thin panel or the like. In these days, for example, even a TV having a 26 inch screen size generally has a thickness of 40 mm or less.

### PRIOR ART DOCUMENTS

### Patent Documents

Patent Document 1: JP 2010-271441 A

### SUMMARY OF INVENTION

### Problems to be Solved by the Invention

In TVs which have been becoming thinner and thinner as described above, particularly in a plasma display TV in which a metal plate is used as a back cover, there is a problem of noise generated from the vicinity of the back cover.

One non-limiting and exemplary embodiment provides a thin-screen TV capable of suppressing the generation of noise from a back cover.

### Means for Solving the Problem

In a conventional plasma display TV before being thinned down, noise from the vicinity of a back cover is not particularly annoying. However, the inventor of the present application has noticed that, in a recent plasma display TV which has been sufficiently thinned down, noise from the vicinity of a back cover is noticeable. Further, the inventor of the present application has assumed that the cause of the noise is a magnetic flux generated by a toroidal coil in an internal circuit. More specifically, a conventional plasma display TV has a reasonable thickness. Therefore, even if toroidal coils are provided in an internal circuit, there is a sufficient distance between the toroidal coils and a back cover. On the other hand, in a recent thin-screen plasma display TV, a toroidal coil in an internal circuit and a back cover are arranged close to each other. Therefore, the inventor of the present application has assumed that, in a recent thin-screen plasma display TV, a back cover vibrates due to the influence of a magnetic flux generated by a toroidal coil in an internal circuit, and noise is generated from the back cover as a result of the vibration, and has invented an image display apparatus having the following configuration.

The image display apparatus according to the present disclosure is an image display apparatus including a circuit board on which a toroidal coil is mounted, and a back cover covering a back face,

wherein the back cover has at least one hole configured to reduce the influence of a magnetic flux generated by the toroidal coil, the hole being provided in a region including a region facing the toroidal coil on the circuit board.

### Effects of the Invention

According to the present disclosure, the influence of the magnetic flux generated by the toroidal coil is reduced by the holes formed on the metallic back cover of the thin-screen TV. Therefore, vibration of the metallic back cover of the thin-screen TV in which the toroidal coil in the internal circuit and the metallic back cover are arranged close to each other is significantly reduced. That is, noise is not substantially generated from the metallic back cover of the thin-screen TV in which the toroidal coil in the internal circuit and the metallic back cover are arranged close to each other.

### BRIEF DESCRIPTION OF DRAWINGS

FIG. 1 is a back view of a thin-screen TV according to a first embodiment of the present disclosure.

FIG. 2 (1) is a plan view of a part of a circuit board in the thin-screen TV according to the first embodiment of the present disclosure; FIG. 2 (2) is a diagram illustrating the configuration of a partial region of a back cover which is provided on the back face of the thin-screen TV in parallel to the circuit board illustrated in FIG. 2 (1); and FIG. 2 (3) is a diagram illustrating a state where the partial region of the back cover illustrated in FIG. 2 (2) is overlapped with the circuit board illustrated in FIG. 2 (1).

FIG. 3 is a cross-sectional view of the thin-screen TV taken along line A-A′ of FIG. 2 (3) in a plane perpendicular to FIG. 2 (3).

### MODE FOR CARRYING OUT THE INVENTION

Hereinbelow, a preferred embodiment according to the present disclosure will be described with reference to the drawings.

### First Embodiment

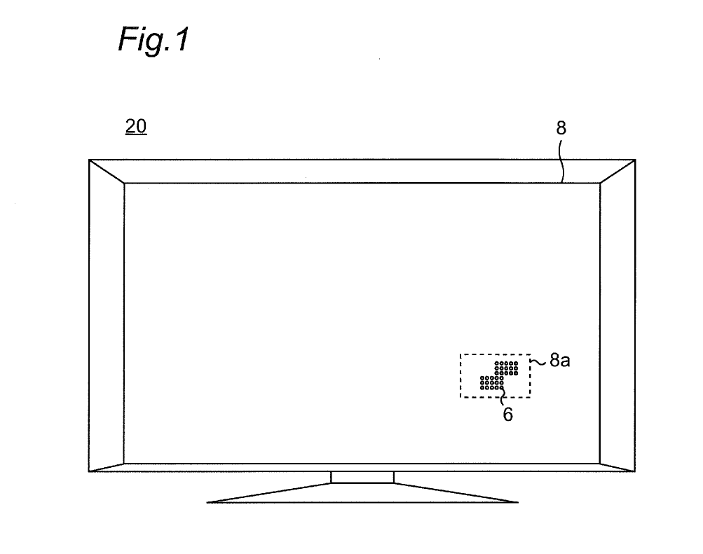

FIG. 1 is a back view of a thin-screen TV 20 according to the first embodiment of the present disclosure. The thin-screen TV 20 is, for example, a plasma display TV. In the back view illustrated in FIG. 1, many holes 6 arranged in a grid pattern are formed in a partial region 8a located on the lower right of a back cover 8. The back cover 8 is made of metal. A toroidal coil is arranged on a circuit board inside the thin-screen TV 20 at a position facing the region of the holes 6 arranged in a grid pattern illustrated in FIG. 1.

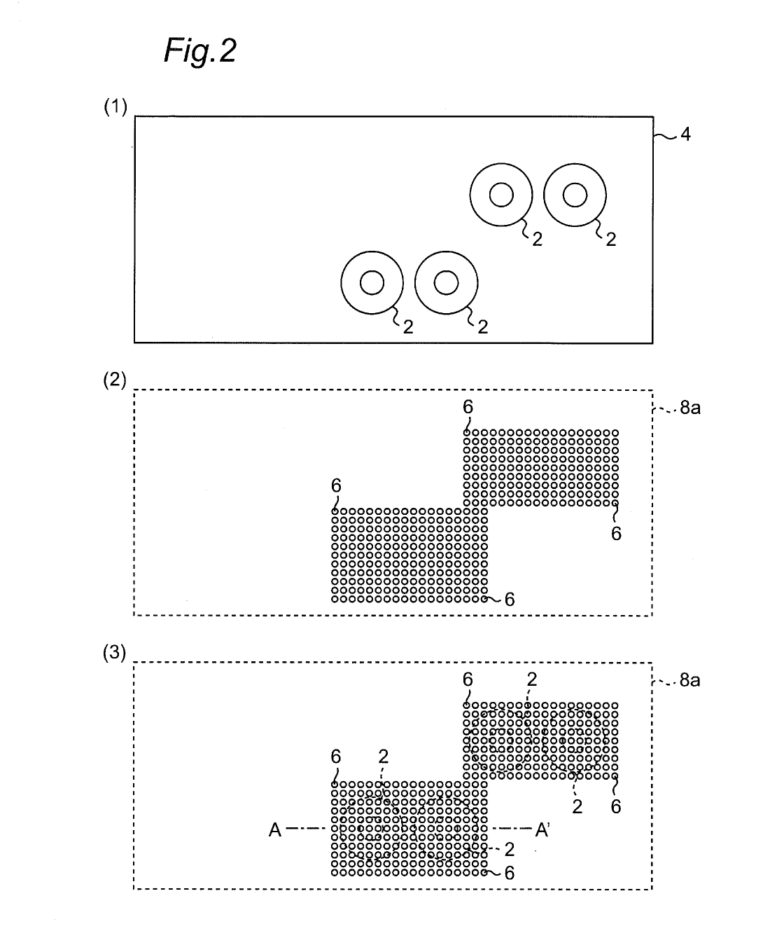

FIG. 2 (1) is a diagram illustrating only a partial region of the circuit board 4 inside the thin-screen TV 20 according to the first embodiment of the present disclosure. In FIG. 2 (1), for convenience of explanation, only some components (toroidal coils 2) in the circuit board 4 are illustrated. The circuit board 4 is arranged in parallel to a front panel inside the thin-screen TV 20. In the circuit board 4 illustrated in FIG. 2 (1), four toroidal coils 2 are mounted. The number of toroidal coils 2 provided in the circuit board 4 may be a number other than four.

FIG. 2 (2) is a diagram illustrating the partial region 8a in the back cover 8 which is arranged at the rear part of the thin-screen TV in parallel to the circuit board 4 illustrated in FIG. 2 (1). The partial region 8a illustrated in FIG. 2 (2) is a region that is overlapped with the circuit board 4 illustrated in FIG. 2 (1) when viewed from the back side of the thin-screen TV 20. As illustrated in FIG. 2 (2), the many holes 6 are arranged in a grid pattern on the upper right part and the lower central part of the partial region 8a of the back cover 8.

FIG. 2 (3) is a diagram illustrating the partial region 8a of the back cover 8 when the back cover 8 is attached to the thin-screen TV 20. As is clear from FIGS. 2 (1), 2 (2), and 2 (3), the holes 6 arranged in a grid pattern are formed at a position on the back cover 8, the position corresponding to a region in which the toroidal coils 2 are arranged on the circuit board 4. As will be described below, the inner side of a region of the holes 6 arranged in a grid pattern is covered by an insulating plate. Therefore, the toroidal coils 2 cannot be directly observed from the back face of the thin-screen TV.

In this manner, the holes 6 in the back cover 8 of the present embodiment is formed in the region (of the back cover 8) that faces the toroidal coils 2 on the circuit board 4. Further, the diameter of the holes 6 and the interval between the holes 6 can be appropriately set. For example, the diameter of the holes 6 can be set to a predetermined value within the range of 4 to 10 mm, and the interval between the holes 6 can be set to a predetermined value within the range of 1 to 5 mm.

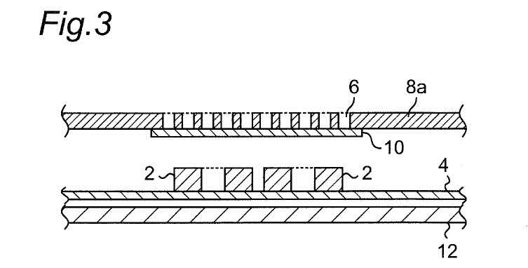

FIG. 3 is a cross-sectional view of the thin-screen TV 20 taken along line A-A′ of FIG. 2 (3) in a plane perpendicular to FIG. 2 (3). In FIG. 3, a front panel 12, the circuit board 4, and the partial region 8a of the back cover 8 are illustrated in parallel from the bottom in this order. Therefore, the downward direction in FIG. 3 corresponds to the front face direction of the TV, and the upward direction thereof corresponds to the back face direction of the TV. As illustrated in FIG. 3, in the partial region 8a of the back cover 8, the plurality of holes 6 arranged in a grid pattern are formed at the position facing the toroidal coils 2.

In the partial region 8a of the back cover 8, an insulation plate 10 which is made of an insulating resin or the like is provided on the inner side of the region of the holes 6 arranged in a grid pattern. The insulation between the toroidal coils 2 and the back cover 8 is ensured by the insulating plate 10. Further, the insulating plate 10 makes it possible to prevent minute objects from entering the inside of the thin-screen TV 20. As will be described below, the insulating plate 10 itself cannot be the factor of the generation of vibration.

As described above, the inventor of the present application has assumed that the cause of noise generated from the vicinity of the back cover 8 is the influence of a magnetic flux generated by toroidal coils. Therefore, in order to reduce the influence of the magnetic flux, the many holes 6 are formed on the back cover 8 of the thin-screen TV 20. In this manner, a metal part of the back cover 8 affected by the magnetic flux is reduced.

That is, as illustrated in FIG. 3, a part of the back cover 8 in which the holes 6 are formed is not affected by the influence of the magnetic flux generated by the toroidal coils 2 to the back cover 8. By forming the many holes 6, parts that are not affected by the influence to the back cover 8 are increased. As a result, vibration of the back cover 8 is significantly reduced, and the back cover 8 therefore substantially does not generate noise.

In the present embodiment, the many holes 6 arranged in a grid pattern are formed in the partial region 8a which includes at least a part of the back cover 8 of the thin-screen TV 20, the part facing the toroidal coils 2 in an internal circuit, so that vibration of the back cover 8 caused by the influence of the magnetic flux generated by the toroidal coils 2 is reduced to thereby prevent the generation of noise from the back cover 8.

The inventor of the present application has experimentally confirmed that noise is generated from the back cover 8 when the back cover 8 is made of metal, and, further, that the noise substantially disappears by utilizing the present embodiment. Further, the inventor of the present application has experimentally confirmed that, even when the toroidal coils 2 have gaps, vibration of the back cover 8 is reduced, and noise generated from the vicinity of the back cover 8 substantially disappears by utilizing the present embodiment.

Further, the inventor of the present application has also confirmed that a back cover that is made of a material other than metal (an insulating resin, for example) hardly vibrates. This fact indicates that a back cover made of a material other than metal (an insulating resin, for example) is not affected by the influence of a magnetic flux generated by toroidal coils 2 in an internal circuit. Therefore, in the present embodiment, the insulating plate 10 (see FIG. 3) which is provided on the inner side of the region of the plurality of holes 6 arranged in a grid pattern in the partial region 8a of the back cover 8 does not constitute the factor of the generation of vibration.

Hereinabove, it has been described that the present embodiment can be applied to a plasma display TV. The present embodiment can also be applied to another kind of TV, for example, a liquid crystal TV as long as a toroidal coil is mounted in an internal circuit and a back cover is made of metal.

### INDUSTRIAL APPLICABILITY

The present invention is utilized in a thin image display apparatus such as a plasma display TV and a liquid crystal TV that has a back cover made of metal.

### DESCRIPTION OF REFERENCE CHARACTERS

2 toroidal coil
4 circuit board
6 hole
8 back cover
10 insulating plate
12 front panel
20 thin-screen TV

1. An image display apparatus comprising:
a circuit board on which a toroidal coil is mounted; and
a back cover covering a back face, wherein
the back cover has at least one hole configured to reduce the influence of a magnetic flux generated by the toroidal coil, the hole being provided in a region including a region facing the toroidal coil on the circuit board.

2. The image display apparatus according to claim 1, wherein the at least one hole comprises a plurality of holes arranged in a grid pattern.

3. The image display apparatus according to claim 2, wherein the diameter of the holes is within the range of 4 to 10 mm, and the interval between the holes is within the range of 1 to 5 mm.
